(19) United States
(12) Patent Application Publication
(10) Pub. No.: US 2002/0164476 A1
(43) Pub. Date: Nov. 7, 2002

(54) CONDUCTIVE SEALING MATERIAL, PROFILED SEALING MEMBER, METHOD

(76) Inventors: HELMUT KAHL, BERLIN (DE); KARL GIELNIK, BERLIN (DE); BERND TIBURTIUS, KLEINMACHNOW (DE)

Correspondence Address: VENABLE, POST OFFICE BOX 34385, WASHINGTON, DC, 20043-9998, US

(21) Appl. No.: 09/242,533

(22) PCT Filed: Aug. 18, 1997
(86) PCT No.: PCT/DE97/01818

(30) Foreign Application Priority Data
Aug. 18, 1996 (DE) 196 34 172.8

(51) Int. Cl. B32B 5/16

(52) U.S. Cl. 428/328; 428/450; 428/329; 252/514; 252/512; 252/513; 252/519.31

(57) ABSTRACT

The invention concerns a conductive sealing material (13/a), in particular for producing a profiled sealing member in situ, with a crosslinkable silicone and metal and/or inorganic fillers, comprising a portion of more than 1 mass % of longchain siloxane which does not crosslink or crosslinks only slightly.

The invention relates to a conductive sealing material as generically defined by the preamble to claim 1 and to a profiled sealing member made from that material.

Electrically conductive sealing materials based on silicone with a conductive filling for producing housing seals with an electromagnetic shielding effect in place (“mold-in-place”) have long been known and became a mass produced product, if not before, then certainly with the use of millions of mobile phones.

Earlier, they were used particularly for adhesive sealing of the individual parts of shielding housings or for adhesive bonding of prefabricated shielding seals during housing assembly and were adjusted accordingly in terms of their properties. For how such seals and corresponding products are made, see the early company brochure 8565/0 “Conductive Materials and Products” (1970) or the data sheet CS-723 “Conductive Caulking Systems” (1972) issued by Tecknit, USA; the Technical Bulletin 46 “CHO-BOND 1038” (1987) issued by Comerics, USA; and German Patent Disclosure DE-A 39 36 534 and British Patent GB-A 2 115 084.

Adhesive bonding of shielding housings during assembly has the decisive disadvantage in terms of utility—along with considerable disadvantages from a production and logistical standpoint—that the housings after assembly cannot be opened again without destroying the seal (and the shielding).

From German Patent Disclosure DE-A 39 34 845, a multiple-part shielding seal is known that comprises an elastic substrate and a highly conductive cover layer and that permits both prefabrication of housing parts with sealing before assembly and repeated opening of the housing after it has first been closed. However, the production of the seal is complicated.

In mass production, the method of European Patent Disclosure EP-B 0 629 114 has therefore become standard, in which the conductive material is applied in a pastelike initial state by means of pressure from a needle or nozzle directly onto a housing part, and solidifies elastically there with adhesion to the surface of the housing part, all in such a way that a shielding profile is formed that is both conductive and elastic, and whose profile shape is determined via the suitable choice of cross-sectional shape and size and the scanning speed of the needle of nozzle, and by the adjustment of such material properties as viscosity, thixotropy, and the speed of hardening or cross-linking. Even if the housing is opened and reclosed repeatedly, this shielding profile has good durability.

With the ever increasing progress in terms of usage on a mass scale and dropping prices for electronic devices that function reliably only with highly effective shielding, there is major cost pressure on the production of shielding housings, and this cost pressure is expressed, among other ways, in the use of less expensive housing materials and in the demand for less-precise production tolerances for the housing parts. In this general area, there is an increased demand for shielding seals whose mechanical properties are improved and which in particular are relatively soft and can be deformed to a high degree, but this demand cannot be met with the known sealing materials.

There is a similarly motivated demand, although in lesser numbers, for thermally conductive seals with improved mechanical properties.

It is therefore the object of the invention to disclose an electrically and/or thermally highly conductive sealing material that allows the production of a profiled sealing member of the “mold-in-place” type with improved mechanical properties that can easily be adjusted over a wide range of values, and in particular with very good adhesion capability and a selectively lesser hardness or high deformability.

With regard to a sealing material as generically defined by the preamble to claim 1, this object is attained by the characteristics disclosed in the body of that claim, and with regard to the profiled sealing member, it is attained by the characteristics of claims 7 and 9.

The invention encompasses the fundamental concept—with regard to the material aspect—of admixing a longchained, non-cross-linking siloxane with a cross-linkable silicone rubber that is filled with metal to a high degree and hardens as a result of cross-linking, forming a gel-like to liquid state. The electrically and/or thermally conductive profiled sealing member formed from this mixture is distinguished by high adhesion strength on the underlay and by a Shore A hardness that can be adjusted to low values and a high possible degree of deformation.

The proportion of long-chained siloxane (silicone oil) that does not cross-link or at most cross-links only weakly in the total mixture—including the metal and/or inorganic filler—is at least 1 mass percent. At lesser proportions, the mechanical properties do not vary substantially compared with a pure silicone rubber base.

If the proportion of non-cross-linking siloxane is more than 3 mass percent, the pastelike material increasingly assumes a gel-like consistency, which permits highly productive, high-quality forming of a dimensionally stable profiled sealing member, without using shaping means, by extrusion from a nozzle or needle that is passed directly over a surface to be sealed. Relatively soft and yet mechanically sufficiently strong EMI shielding profiles have been extruded with materials filled to a high degree (to over 50 mass percent) with metal powder, and which along with approximately 15-20 mass percent of cross-linkable silicone components (commercially available single- or dual-component mixtures) contain approximately 5 mass percent of difunctional non-cross-linking siloxane, such as (poly)dimethylsiloxane with methyl or hydroxyl terminal groups, with a viscosity in the range between 10 and 103 mPa.s.

The admixture of the relatively long-chain siloxane that as such is non-cross-linked, results for the material, after hardening of the cross-linkable silicone component (by humidity, heat or radiation), in a wide-mesh cross-linked structure with a certain plasticity, the degree of which can be predetermined via the mixture ratio. To form highly plastic seals for special applications where the demands for dimensional stability are only slight, the proportion of non-cross-linked component can be increased up to a multiple of the proportion of the cross-linkable component.

The selectively additional addition of an organic solvent serves on the one hand to optimize the processing properties of the material and on the other can have a favorable effect on the usage properties of the finished profiled member. It causes the matrix material to “float” in a sense, and in particular makes mixing of the components easier and improves the wetting. Good results have been obtained in this respect with proportions of between 5 and 20 mass percent of benzene and/or toluene.

The proportion of solvent, for special applications—for instance for “mold-in-place” seals made by doctor blade or spray application or immersion on or of housing edges—can thus be considerably higher and can amount to as much as a multiple of the proportion of basic or matrix mixture.

In a refinement that is advantageous for certain applications, a silicone resin component may also be provided in the sealing material, preferably a proportion of over 3 mass percent of a solution of a commercially available thermal- or radiation-hardening resin component.

Sealing material with high electrical conductivity for producing EMI shields is filled in particular with a high proportion of silver powder or a silvered powder of some other metal (nickel, copper, or the like). The metal content is typically over 25 mass percent, and for economically attaining high shielding effects in mobile phones or the like it is even far above 50 mass percent, referred to the mass of the silicone/silicone oil/metal mixture.

Materials for use for highly thermally conductive seals can include, along with metal powder—especially whenever the seal is not intended to be electrically conductive—a filling of powdered aluminum oxide, boron nitride, or some similar highly thermally conductive inorganic compound. Both types of materials can additionally contain fillers for fine adjustment of the processing and mechanical properties, examples being highly dispersed silicone dioxide or silicates.

The hardness of the hardened profiled sealing member, measured by the Shore process for determining the elastic penetration depth of a spring-loaded testing pin (Shore A hardness) is below 90 and preferably below 50.

The degree of deformation of a finished U-shaped profiled sealing member of solid material can amount to 30% or more (referred to the height of the unstressed profile member) and for certain applications preferably up to over 50%. By means of special profile cross-sectional designs, such as the choice of a lip profile that is both compressible and deformable by bending, the effective degree of deformation and the restoring force of the profiled sealing member can additionally be varied in a targeted way.

By means of the aforementioned provisions in terms of material and optionally also geometry, even gaps whose widths varies considerably over their length can be reliably sealed off in a shielding way or with adequate heat transfer. By way of example, this economically allows higher tolerances in the production of housings for electronic devices in which highly effective electromagnetic shielding is functionally decisive.

Advantageous further features of the invention are also defined in the dependent claims and will be described in further detail below in the context of the description of preferred embodiments of the invention in conjunction with the drawings. Shown are:

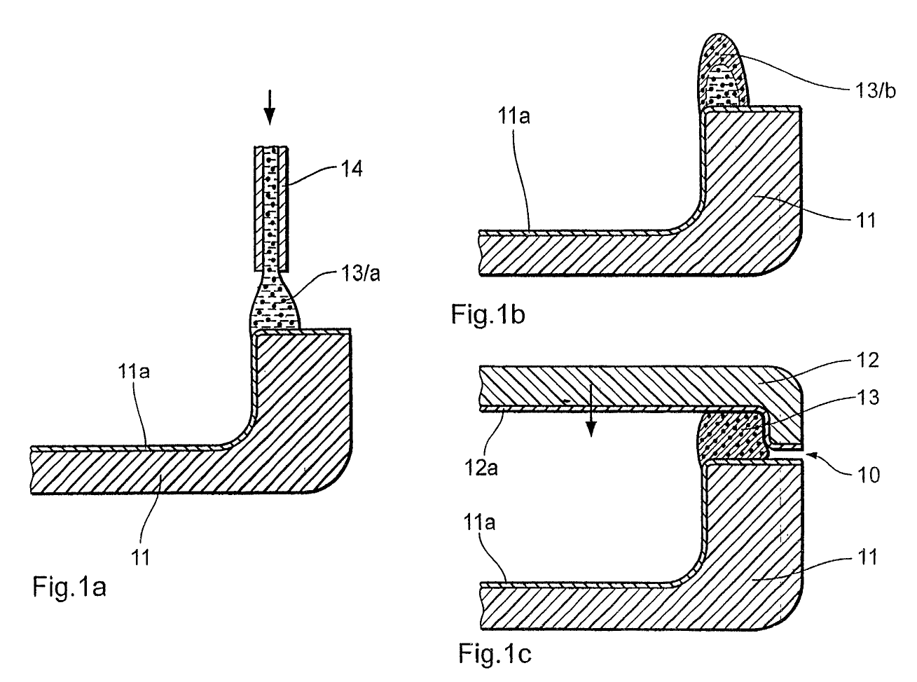

FIGS. 1a-1c, steps in the manufacture of a shielding housing with an electrically conductive profiled sealing member, in one embodiment;

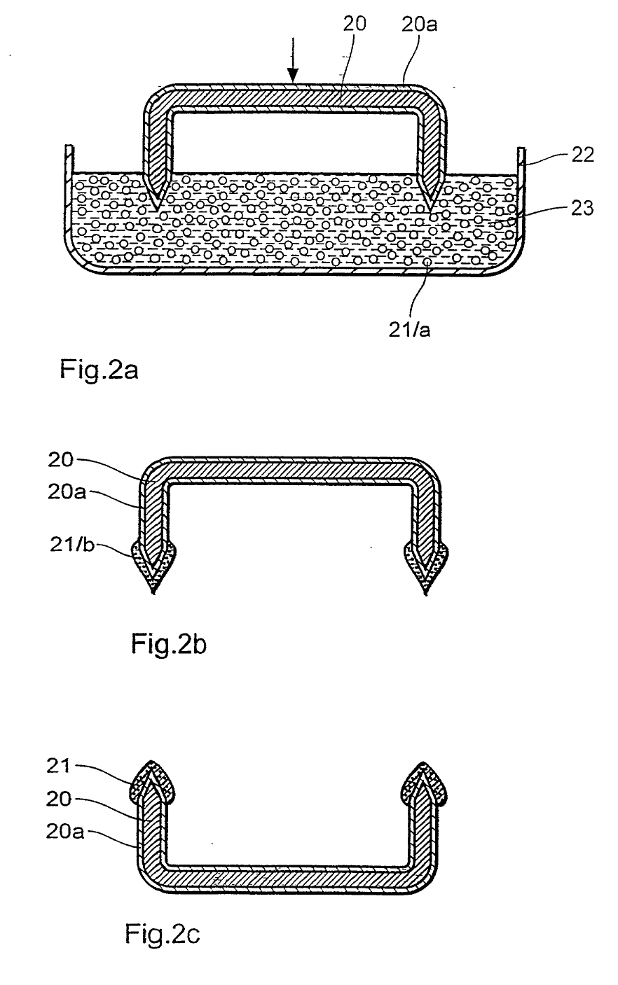

FIGS. 2a-2c, steps in the formation of a conductive profiled sealing member on a housing part in accordance with a further embodiment; and

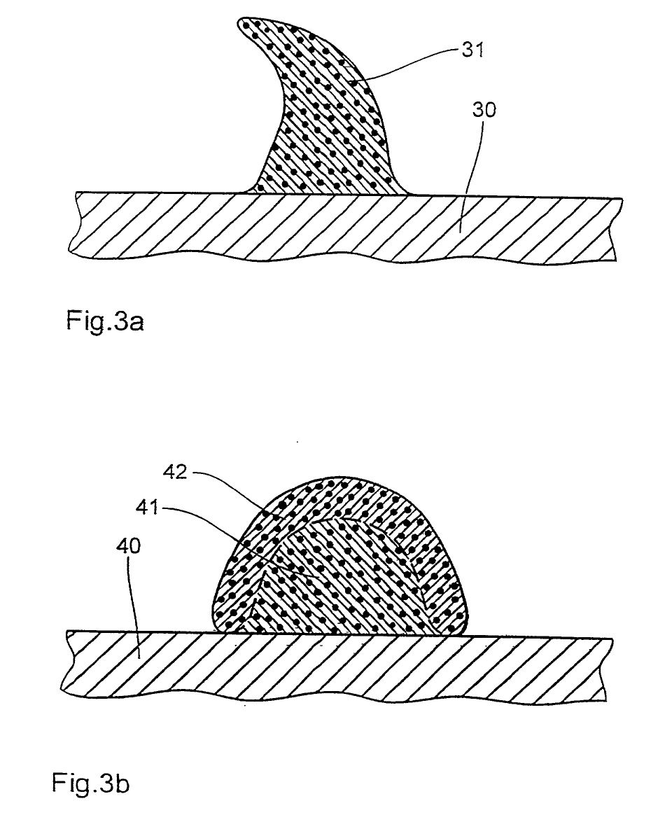

FIGS. 3a and 3b, cross-sectional views of profiled sealing members, as further exemplary embodiments.

As the first exemplary embodiment of the invention, an electrically conductive sealing material is given below as mixture 1 in the following table; it is a heat-hardening single-component system, and after hardening the result is a shielding profiled sealing member with a Shore A hardness of approximately 50. This material, which after hardening is elastic but relatively soft, is suitable for the production of shielding profiles on housing edges of reclosable EMI housings with moderate production tolerances.

Mixture 1

| | | Proportion |
|---|---|---|
| | | (mass percent) |
| Component I: | Silicone “TSE 3220” made | 13.6 |
| | by GE | |
| II: | Polydimethylsiloxane with | 4.5 |
| | methyl or hydroxyl terminal | |
| | groups (dynamic viscosity | |
| | 20 ... 500 mPa.s) | |
| III: | Silicone resin solution, | 8.2 |
| | GE “PSA 529” | |
| IV: | Toluene | 6.8 |
| V: | Benzene | 8.9 |
| VI: | Silver powder | 58.0 |

As the second exemplary embodiment, an electrically conductive sealing material is given below as mixture 2, which is a dual-component system that hardens at room temperature and that after hardening produces a shielding profiled sealing member with a Shore A hardness of approximately 20. The shielding profile formed from this material has a high degree of deformation, exhibits marked plasticity, and is especially suitable for shielding gaps in EMI shielding housings with considerable production tolerances.

Mixture 2

| | | Proportion |
|---|---|---|
| | | (mass percent) |
| Component 1/A: | Silicone GE “SLE 5300 A” | 14.44 |
| 2/B: | Silicone GE “SLE 5300 B” | 1.44 |
| II: | Polydimethylsiloxane with | 5.6 |
| | methyl terminal groups | |
| | (viscosity approximately | |
| | 50 mPa.s) | |
| III: | Toluene | 5.62 |
| IV: | Silvered nickel powder | 72.9 |

In FIGS. 1a-1c, steps in the production of a shielding housing 10, comprising two housing parts 11 and 12, with an electrically conductive profiled sealing member 13 are sketched.

In a first step, shown in FIG. 1a, a metal-filled sealing composition 13/a of gel-like consistency (for instance, the above Mixture 1 or 2) is extruded from an applicator needle 14 onto the housing part 11, which is provided on an inside with a metallizing 11a that covers the edge of the housing part. To that end, the applicator needle 14 is moved relative to the housing part 11 in the direction perpendicular to the plane of the drawing by means of a coordinate-controlled manipulation device (not shown).

As can be seen in FIG. 1b, this creates an approximately U-shaped profiled sealing member 13/b that adheres firmly to the metallizing layer 11a and that after application has begun to cross-link in wide-mesh fashion from the surface—depending on the specific composition—under the influence of humidity and/or heat (infrared radiation) and/or ultraviolet or gamma radiation.

After complete cross-linking, resulting in the finished profiled sealing member 13 (or in any case after cross-linking of a sufficiently thick surface layer, the second housing part 12—as FIG. 1c shows—is placed on vertically from above, this housing part being adapted in terms of its edge design to the unstressed shape of the profiled sealing member 13, and is joined (by means not shown here) to the first housing part 11. In this process, the profiled sealing member 13 is compressed to approximately half its original height and because of its low hardness it conforms closely, with the development of only relatively slight restoring force, to the metallizing layers 11a and 12a of the respective housing parts 11, 12, but without adhering to them. On the one hand, this assures highly effective edge sealing and shielding, even if the gap dimension varies considerably over the housing length and under some circumstances during use of the housing 10 as well. On the other, the housing can be opened for maintenance or repair purposes and reclosed again without destroying the seal and shield 13.

In FIGS. 2a-2c, steps in forming a conductive profiled sealing member 21 on a housing part 20 by an immersion process are sketched.

A metal-filled sealing material 21/a based on silicone and silicone oil and highly diluted is located in an organic solvent 23 in a container 22. As shown in FIG. 2a, the V-shaped edge region of the housing part 20, which is provided with a closed surface metallizing 20a, is dipped into the solution.

After being removed from the solution 23 and after evaporation of the solvent component, a layer 21/b of the sealing material adheres to the housing part; in this phase, shown in FIG. 2b, the sealing material has a pastelike to gel-like consistency and is beginning to harden from the surface by cross-linking of the cross-linkable silicone component.

As can easily be seen from FIGS. 2b and 2c, the final shape of the profiled sealing member 21 can be controlled by rotating the housing part 20 about a predetermined angle at a predetermined time before hardening is complete, because the shape develops under the influence of gravity G. On being moved to the position shown in FIG. 2c, only after partial hardening of the volume, a greater fraction of the volume of the sealing composition will have accumulated at the point of the “V” (which is at the bottom in FIG. 2b) than if the housing part 20 were inverted too early.

It can easily be seen that a similar effect also occurs if the edge portion is shaped differently. For instance, in a surface region with U- or V-shaped grooves, a proportionally greater fraction of the sealing volume will form in the region of the groove bottom, the earlier the housing part is inverted during the progressive cross-linking.

The effect attainable by a change of orientation of the underlay relative to the force of gravity can also be exploited not only in the context of an immersion application process but in a similar way for a seal that is extruded on or sprayed on.

By rotating the housing part about an angle other than 180° after removal from the solution, an oblique-angled or lip-shaped profile in which bending deformation is easily possible can be achieved in a targeted way.

This kind of profile design, as schematically shown in FIG. 3a by the cross section of a shielding profile 31 on a flat housing portion 30, offers additional degrees of freedom in optimizing the deformability and dimensional stability.

In FIG. 3b, a further refinement of the concept of the invention is shown. A first partial profile 41 with very good adhesion strength, low hardness, and a certain plasticity (for instance comprising a silicone mixture similar to mixture 2 given above) is first created on a housing portion 40. Next, from a material (such as a mixture with a low proportion of non-cross-linking siloxane or even without any such siloxane) that is compatible with the material of the first partial profile 41, a second partial profile 42 of greater elasticity and hardness is formed that covers the first partial profile 41.

The two profile members 41, 42 together result in a shielding seal that on the one hand is relatively soft and can be deformed to a high degree and on the other is durable, especially for shielding housings that have to be opened and closed again frequently.

The invention is not limited in its embodiment to the preferred exemplary embodiments described above. On the contrary, many variants are conceivable that make use of the realization shown in the context of the appended claims, even in embodiments of other types.

1. A conductive sealing material (13/a; 21/a), in particular for mold-in-place molding of a profiled sealing member (13; 21; 31; 41, 42), having a cross-linkable silicone and a metal and/or inorganic filler, characterized by a proportion of more than 1 mass percent of long-chained, non-cross-linking or weakly cross-linking siloxane.

2. The sealing material of claim 1, characterized by a proportion of the non-cross-linking or weakly cross-linking siloxane of more than 3 mass percent.

3. The sealing material of claim 1 or 2, characterized by a proportion of more than 3 mass percent of an organic solvent.

4. The sealing material of one of the foregoing claims, characterized by a proportion of more than 3 mass percent of a solution of a cross-linkable silicone resin.

5. The sealing material of claim 1, 3 or 4, characterized in that the proportion of non-cross-linking or weakly cross-linking siloxane and/or organic solvent exceeds the proportion of cross-linkable silicone, and the sealing material is liquid.

6. The sealing material of one of the foregoing claims, characterized by a proportion of more than 25 and preferably more than 50 mass percent of an electrically highly conductive powdered metal filler, in particular comprising silver, silvered copper, or nickel.

7. The profiled sealing member (13; 21; 31; 41, 42), which is made self-supporting by the application of a sealing material of one of claims 1-6 to a surface to be sealed and ensuing hardening, characterized by a Shore A hardness of 90 or less.

8. The profiled sealing member of claim 7, characterized by a Shore A hardness of 50 or less.

9. The profiled sealing member (13; 21; 31; 41, 42), which is made self-supporting by the application of a sealing material of one of claims 1-6 to a surface to be sealed and ensuing hardening, characterized by a degree of deformation of over 30%, referred to the height of an unstressed U-shaped profiled sealing member of solid material.

10. The profiled sealing member of claim 9, characterized by a degree of deformation of over 50%.

11. The profiled sealing member of one of claims 7-10, characterized in that it is produced by extrusion without any additional shaping means.

12. The profiled sealing member of one of claims 7-10, characterized in that it is produced by immersion of the surface to be sealed in liquid sealing material (23, 21/a) and ensuing shape-impressing hardening with a predetermined orientation to gravity (G).

13. The profiled sealing member of one of claims 7-12, characterized by a cross-sectional shape, in particular a lip shape (31), that is asymmetrical with respect to the normal to the underlay (30) at the site of adhesion thereto.

14. The profiled sealing member of one of claims 7-13, characterized by the embodiment of a first conductive profiled member (41) of lesser Shore A hardness and greater deformability and a second conductive profiled member (42), connected to the first in firmly adhering fashion, with greater Shore A hardness and lesser deformability.
